(19) United States
(12) Patent Application Publication
(10) Pub. No.: US 2007/0004129 A1
(43) Pub. Date: Jan. 4, 2007

(54) SEMICONDUCTOR DEVICE HAVING FINFET AND METHOD OF FABRICATING THE SAME

(76) Inventors: Ju-Yong LEE, Gyeonggi-do (KR); Tae-Young CHUNG, Gyeonggi-do (KR); Kyu-Hyun LEE, Gyeonggi-do (KR); Yong-Sung KIM, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 11/427,734

(22) Filed: Jun. 29, 2006

(30) Foreign Application Priority Data
Jun. 30, 2005 (KR) 10-2005-0058552

(51) Int. Cl. H01L 21/8242; H01L 29/94

(52) U.S. Cl. 438/243; 257/296

(57) ABSTRACT

In one embodiment, a semiconductor device includes a plurality of fin-shaped active regions defined by a trench formed in a substrate with a predetermined depth; an isolation layer formed inside the trench and comprising a first insulating material; and a plurality of word lines formed on the isolation layer inside the trench and covering a sidewall of the active region inside the trench. A separation layer is formed between two neighboring word lines to separate the two neighboring word lines of the plurality of word lines inside the trench with a predetermined distance. The separation layer comprises a second insulating material having an etch selectivity with respect to the first insulating material.

### CROSS-REFERENCE TO RELATED PATENT APPLICATION

This application claims the benefit of Korean Patent Application No. 10-2005-0058552. filed on Jun. 30, 2005, in the Korean Intellectual Property Office, the disclosure of which is incorporated herein in its entirety by reference.

### BACKGROUND

1. Field of the Invention

The present invention relates to a semiconductor device and its method of fabrication, and more particularly, to a semiconductor device having a fin field effect transistor (FinFET) formed by word lines formed inside a trench of a semiconductor substrate, and its method of fabrication.

2. Description of the Related Art

A semiconductor device, particularly a planar field effect transistor, highly integrated in its embodiments of high performance, high speed, low power consumption, and economic benefits, has many possible problems that can deteriorate its characteristics. The problems include a short channel effect, such as punch-through, drain induced barrier lowering (DIBL), subthreshold swing, increase of parasitic capacitance between a junction region and a substrate, increase of leakage current, and the like. A shortened channel length of the field effect transistor further exacerbates these problems.

Many efforts have been made to alleviate these problems, and FinFET technology has been proposed as one example. As both sidewalls of a silicon fin as an active region are used as a channel in the process of forming a FinFET, current characteristics can be improved without increasing an occupancy area on a wafer. Further, the FinFET technology has advantages of more simplified formation processes and reduced fabrication costs.

In the conventional process of forming a FinFET, a portion of a semiconductor substrate is etched to form a trench, thereby forming a silicon fin. Then, an insulating layer for isolation is buried in the trench to electrically isolate neighboring silicon fins, and a mask pattern is formed on the insulating layer for isolation to expose the sidewall of the silicon fin. A portion of the insulating layer for isolation is removed by a wet etch process using the mask pattern as an etch mask. At this time, it is difficult to precisely control an etch amount in the wet etch process. As a result, a portion of the insulating layer, which must remain inside the trench, may also be removed in addition to the portion of the insulating layer for isolation, which is etched to expose the sidewall of the silicon fin. If word lines are formed on the resultant structure in this state, then there is a highly increased possibility that a bridge phenomenon is generated between neighboring word lines inside the trench.

FIG. 1A is a scanning electron microscope (SEM) image, in plan view, illustrating a FinFET formed on a semiconductor substrate by a conventional method.

FIG. 1B is an SEM image illustrating a cross-sectional view of a portion indicated by ‘B’ in FIG. 1A.

Referring to FIGS. 1A and 1B, a trench 30 defining an active region 20 of a semiconductor substrate is formed by the conventional method, and an insulating layer for isolation 32 is buried into the trench 30. A mask pattern is formed on the insulating layer for isolation using a photolithography process. The insulating layer for isolation 32 is partially removed by a wet etch process using the mask pattern as an etch mask so as to form a space. A word line 50 is then formed in the space.

In the portion indicated by “B” in FIG. 1B, a bridge exists between two neighboring word lines 50 inside the trench 30.

### SUMMARY

Some embodiments of the present invention provide a semiconductor device having a structure without a bridge between two neighboring word lines inside a trench in realizing a fin field effect transistor (FinFET) using the trench.

Some embodiments of the present invention also provide a method of fabricating a semiconductor device capable of avoiding bridge generation between two neighboring word lines inside a trench by ensuring resistance with respect to a wet etch process when removing an insulating layer for isolation in realizing a FinFET using the trench.

According to an embodiment of the present invention, a semiconductor device includes a plurality of fin-shaped active regions defined by a trench formed in a semiconductor substrate with a predetermined depth; an isolation layer formed inside the trench and comprising a first insulating material; and a plurality of word lines formed on the isolation layer inside the trench and covering a sidewall of the active region inside the trench. A gate insulating layer is formed between the active region and the word line. A separation layer is formed between two neighboring word lines to separate the two neighboring word lines of the plurality of word lines inside the trench with a predetermined distance. The separation layer composes a second insulating material having an etch selectivity with respect to the first insulating material.

The separation layer may directly contact a bottom surface of the trench. Further, the separation layer may be formed inside the trench with a shallower depth than that of the trench.

The word line may have a first surface facing the active region inside the trench, and has a second surface facing the separation layer inside the trench. The second surface of the word line may directly contact the separation layer.

According to another embodiment of the present invention, a method of fabricating a semiconductor device includes partially etching the semiconductor substrate, thereby forming a trench with a predetermined depth defining a plurality of fin-shaped active regions extending along a first direction in the semiconductor substrate. An isolation layer comprising a first insulating material is formed inside the trench. By partially removing the isolation layer, a separation space is formed inside the trench. The inside of the separation space is filled with a separation layer comprising a second insulating material having an etch selectivity with respect to the first insulating material. By partially removing the isolation layer, a gate space is formed between the separation layer and the active region inside the trench while exposing respective sidewalls of the separation layer and the active region. A gate insulating layer is formed on an upper surface and a sidewall of the active region. A plurality of word lines filling the gate space are formed on the gate insulating layer.

The operation of forming the separation space inside the trench may include forming an etch mask pattern covering a predetermined region for word lines on the isolation layer; and etching a portion of the isolation layer exposed through the etch mask pattern. The operation of forming the separation space may be performed by etching the isolation layer until a bottom surface of the trench is exposed. Further, the etching of forming the separation space may be stopped before a bottom surface of the trench is exposed.

The semiconductor substrate may be dry-etched to form the trench, using the hard mask pattern covering the active region as an etch mask. The etch mask pattern may be formed both on the isolation layer and the hard mask pattern, and the isolation layer may be dry-etched to form the separation space inside the trench, using the hard mask pattern and the etch mask pattern as etch masks. Further, the isolation layer may be etched back to form the gate space, using the separation layer and the hard mask pattern as etch masks. After forming the gate space, the method may further include exposing an upper surface of the active region by removing the hard mask pattern.

In realizing a FinFET using a trench according to the present invention, a photolithography process of forming a mask pattern is not necessary when etching an insulating layer for isolation to expose the sidewall of an active region inside the trench, and by forming word lines, which are self-aligned with the active region and the separation layer, inside the trench. Bridge generation between the adjacent word lines inside the trench can be avoided.

### BRIEF DESCRIPTION OF THE DRAWINGS

The above and other features and advantages of the present invention will become more apparent by describing in detail exemplary embodiments thereof with reference to the attached drawings in which:

FIG. 1A is a scanning electron microscope (SEM) image, in plan view, illustrating a FinFET formed on a semiconductor substrate by a conventional method;

FIG. 1B is an SEM image illustrating a cross-sectional view of a portion indicated by ‘B’ in FIG. 1A;

FIGS. 2A and 2B through FIGS. 8A and 8B are views illustrating a method of fabricating a semiconductor device in accordance with processing sequences according to an embodiment of the present invention; and

FIG. 9 is a perspective view schematically illustrating a cut-away portion indicated by “A” in FIG. 8A.

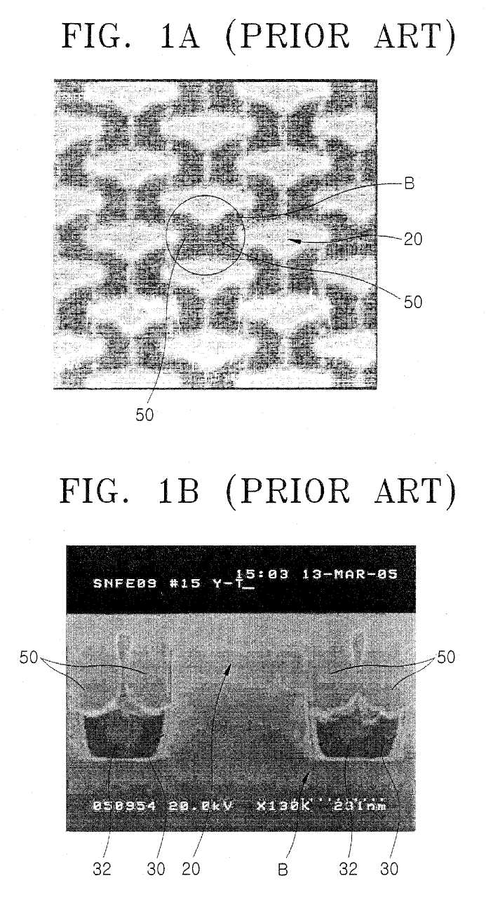

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification.

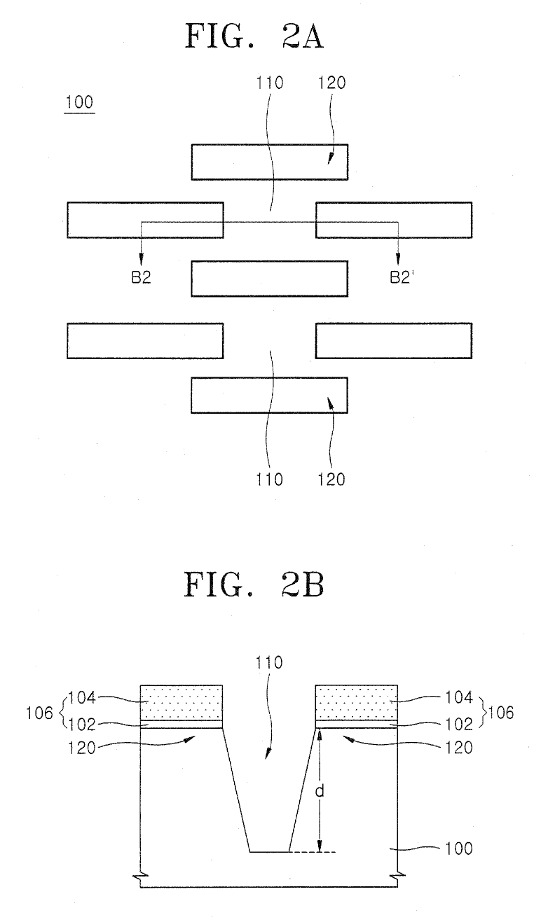

FIGS. 2A and 2B through FIGS. 8A and 8B are views illustrating a method of fabricating a semiconductor device according to an embodiment of the present invention. Hereinafter, a method of fabricating a semiconductor device according to an embodiment of the present invention will be explained in more detail with reference to the drawings.

FIGS. 2A and 2B are views illustrating an island-shaped fin-type active region 120, which is defined by a trench 110, formed in a semiconductor substrate 100.

FIG. 2A is a plan view illustrating the layout of the active region 120 defined by the trench 110 in the semiconductor substrate 100, and FIG. 2B is a cross-sectional view taken along line B-B′ of FIG. 2A. Some of the elements shown in the cross-sectional view of FIG. 2B are omitted in the plan view of FIG. 2A.

In detail, after a pad oxide layer 102 and a silicon nitride layer 104 are sequentially formed on a semiconductor substrate 100, they are patterned, thereby forming a hard mask pattern 106 exposing an isolation region that will become the trench 110 of the semiconductor substrate 100. To form the hard mask pattern 106, the pad oxide layer 102 is formed with a thickness of, for example, about 30 Å to about 50 Å, and the silicon nitride layer 104 may be formed with a thickness of about 800 Å.

Then an exposed portion of the semiconductor substrate 100 is dry-etched down to a predetermined depth, using the hard mask pattern 106 as an etch mask, thereby forming the trench 110. For example, the trench 110 may be formed with a depth “d” of about 3000 Å. As a result, a fin-shaped active region 120 is defined in the semiconductor substrate 100 to extend along a predetermined direction. The active region 120 is defined by partially etching the semiconductor substrate 100, and is formed integrally with the semiconductor substrate 100.

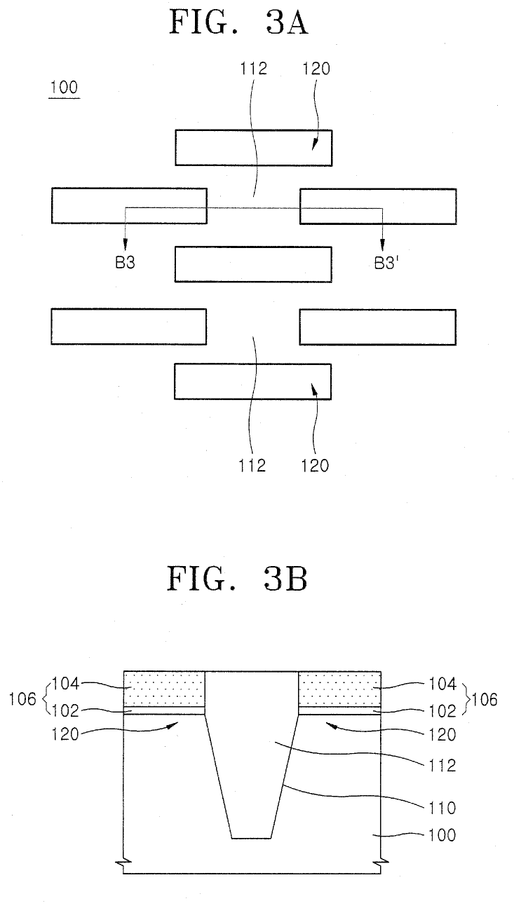

FIGS. 3A and 3B are views illustrating an isolation layer 112 formed in the trench 110 of the semiconductor substrate 100. FIG. 3A is a plan view illustrating that the isolation layer 112 buried in the trench 110 around the active region 120 in the semiconductor substrate 100, and FIG. 3B is a cross-sectional view taken along line B3-B3′ of FIG. 3A. Some of the elements shown in the cross-sectional view of FIG. 3B are omitted in the plan view of FIG. 3A for the sake of simplicity.

In detail, after a silicon oxide layer is deposited on the overall surface of the semiconductor substrate 100 having the trench 110, a chemical mechanical polishing (CMP) process is performed using an etch selectivity between the silicon nitride layer 104 of the hard mask pattern 106 and the silicon oxide layer, thereby forming the isolation layer 112 that buries the trench 110.

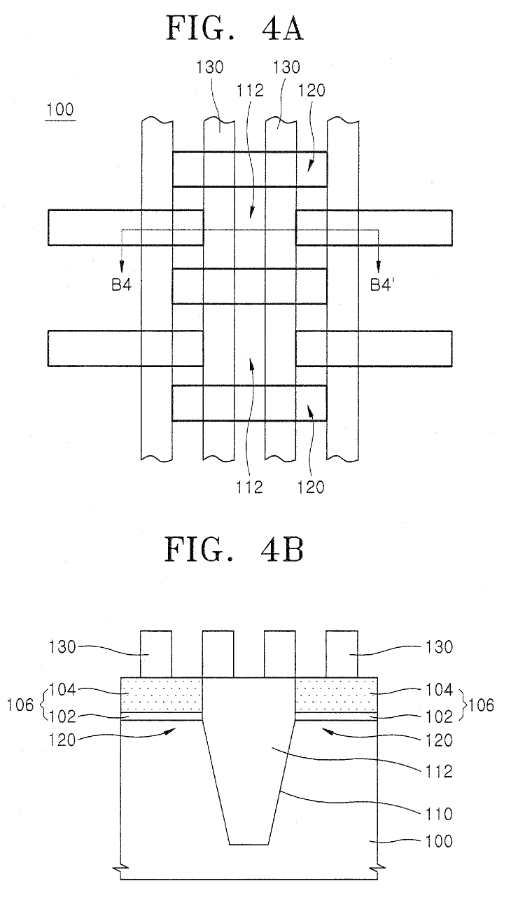

FIGS. 4A and 4B are views illustrating an etch mask pattern 130 formed to cover the upper surface of the isolation layer 112 and a predetermined region for word lines on the active region 120. FIG. 4A is a plan view illustrating a layout of an etch mask pattern 130 formed on the active region 120 and the isolation layer 112, and FIG. 4B is a cross-sectional view taken along line B4-B4′ of FIG. 4A. Some of the elements shown in the cross-sectional view of FIG. 4B are omitted in the plan view of FIG. 4A for the sake of simplicity.

In detail, the etch mask pattern 130 is formed on the upper surface of the isolation layer 112 and over the active region 120 to extend along a direction perpendicular to the extension direction of the active region 120. The etch mask pattern 130 is formed corresponding to the position where a word line will be formed in a subsequent process.

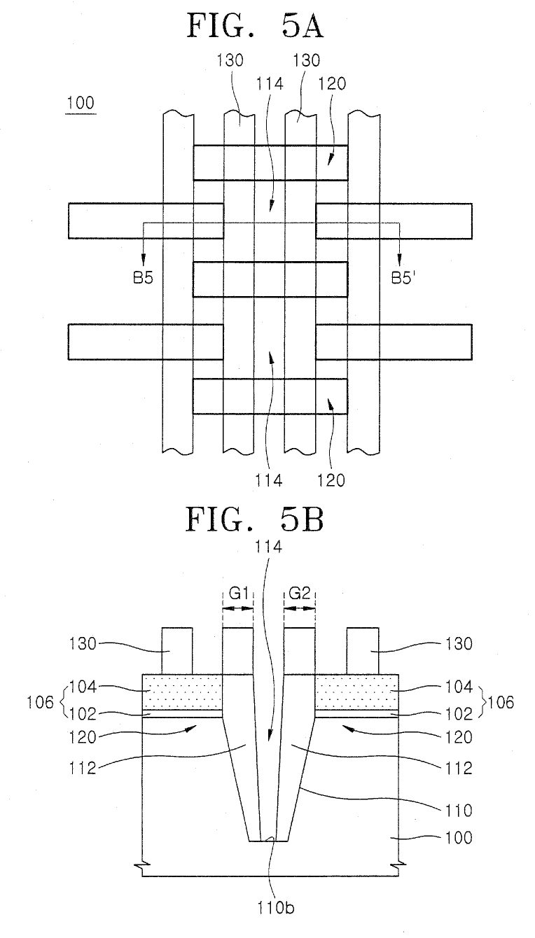

FIGS. 5A and 5B are views illustrating a process of etching a portion of the isolation layer 112, thereby forming a separation space 114 to separate respective gate regions G1, G2 of two fin-shaped transistors which will be formed adjacent to each other inside an isolation region where the trench 110 is formed in a subsequent process.

FIG. 5A is a plan view illustrating a bottom surface 110b of the trench 110 exposed at an isolation region exposed through the etch mask pattern 130. FIG. 5B is a cross-sectional view taken along the line B5-B5′ of FIG. 5A. Some of the elements shown in the cross-sectional view of FIG. 5B are omitted in the plan view of FIG. 5A.

In detail, the isolation layer 112 exposed between the silicon nitride layer 104 and the etch mask pattern 130 may be removed, for example, by a dry etch process using the silicon nitride layer 104 and the etch mask pattern 130 covering the active region as etch masks, thereby exposing a bottom surface 110b of the trench 110. As a result, a separation space 114 is formed inside the trench 110 formed at the isolation region. The separation space 114 provides a space necessary to electrically isolate two gates to be formed adjacently at the gate regions G1, G2 during a subsequent process.

FIGS. 5A and 5B illustrate an example of etching the isolation layer 112, using the etch mask pattern 130 as an etch mask, until the bottom surface 110b of the trench 110 is exposed. However, the present invention is not limited thereto. That is, the etch process of forming the separation space 114 may be stopped before the bottom surface 110b of the trench 110 is exposed, and thus, the separation space 114 may be formed with a shallower depth than a depth “d” of the trench 110 (refer to FIG. 2B).

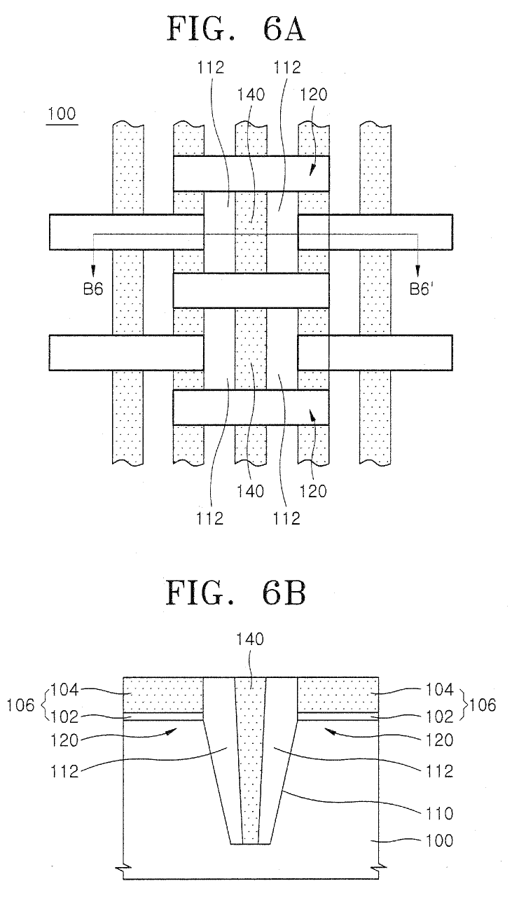

FIGS. 6A and 6B are views illustrating a process of forming a separation layer 140 inside the separation space 114.

FIG. 6A is a plan view illustrating the separation layer 140 formed in the separation space 114 between the two neighboring gate regions G1, G2 inside the trench 110. FIG. 6B is a cross-sectional view taken along line B6-B6′ of FIG. 6A. Some of the elements shown in the cross-sectional view of FIG. 6B are omitted in the plan view of FIG. 6A for the sake of simplicity.

In detail, after the etch mask pattern 130 is removed, an insulating material is deposited over the resultant structure having the separation space 114. The insulating material may be the same material as the silicon nitride layer 104 of the hard mask pattern 106, that is, silicon nitride. Then, a CMP process is performed until an upper surface of the silicon nitride layer 104 of the hard mask pattern 106 is exposed, using an etch selectivity between the silicon oxide layer and the silicon nitride layer. As a result, the separation layer 140 comprising silicon nitride is formed in the separation space 114 between the two neighboring regions G1, G2 inside the trench 110. FIG. 6B illustrates that the separation layer 140 directly contacts a bottom surface of the trench 110. However, the present invention is not limited thereto. That is, if the separation space 114 is formed with a shallower depth than a depth “d” of the trench 110, the separation layer 140 is formed inside the trench 110 with a shallower depth than the depth of the trench 110.

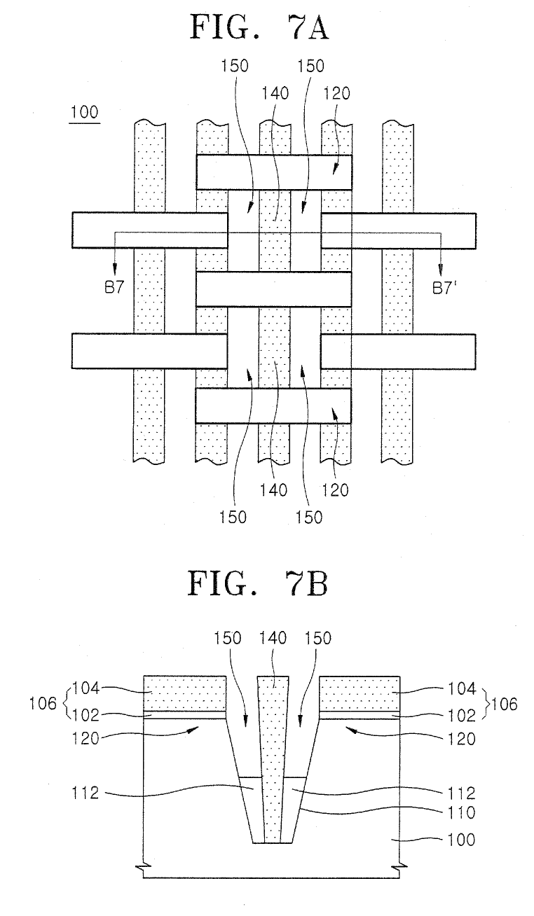

FIGS. 7A and 7B are views illustrating a process of removing a portion of the isolation layer 112 to form a gate space 150 of a fin-shaped transistor in the gate regions G1, G2 inside the trench 110. FIG. 7A is a plan view illustrating a layout of the gate space 150 of the transistor formed in the gate regions G1, G2. FIG. 7B is a cross-sectional view taken along line B7-B7′ of FIG. 7A. Some of the elements shown in the cross-sectional view of FIG. 7B are omitted in the plan view of FIG. 7A for the sake of simplicity.

In detail, the isolation layer 112 inside the trench 110 is etched down to a predetermined depth, that is, a depth necessary to form a gate, for example, about 1500 Å, using the silicon nitride layer 104 of the hard mask 106 and the separation layer 140 exposed on the semiconductor substrate 100 as etch masks, thereby forming a gate space 150 inside the trench 110. A sidewall of the active region 120 and a sidewall of the separation layer 140 are exposed inside the gate space 150.

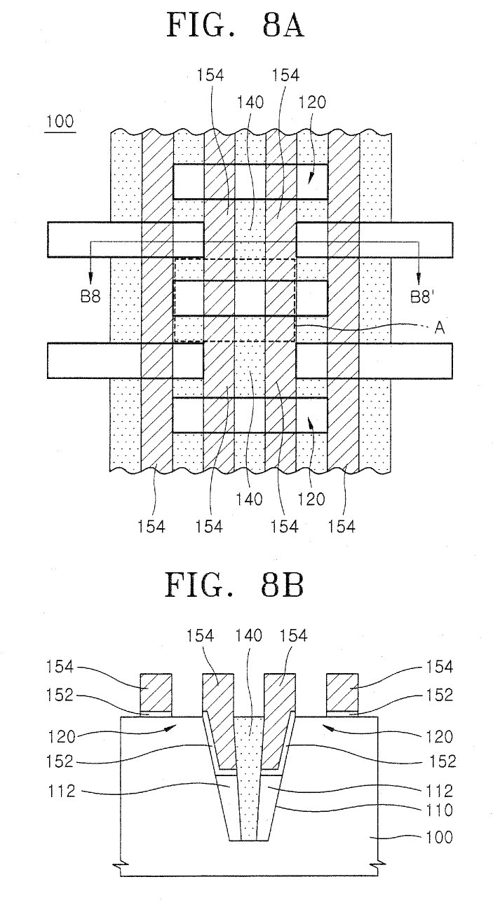

FIGS. 8A and 8B are views illustrating a process of forming a word line 154 in the gate space 150. FIG. 8A is a plan view illustrating a layout of the word line 150 extending along a vertical direction with respect to an extension direction of the active region 120. FIG. 8B is a cross-sectional view taken along line B8-B8′ of FIG. 8A. Some of the elements shown in the cross-sectional view of FIG. 8B are omitted in the plan view of FIG. 8A for the sake of simplicity.

In detail, the silicon nitride layer 104 and the pad oxide layer 102 of the hard mask 106 are sequentially removed from the resultant structure of FIGS. 7A and 7B. For this purpose, a wet etch process may be used. As a result, an upper surface of the active region 120 is exposed. Further, the separation layer 140 formed inside the trench 110 is also consumed during the etching of the silicon nitride layer 104 so that its height is reduced down as shown in FIG. 8B.

Then a gate insulating layer 152 is formed on the exposed surface of the fin-shaped active region 120 on the semiconductor substrate 100. The gate insulating layer 152 may be formed by, for example, thermally oxidizing the exposed surface of the active region 120. After a conductive layer for forming a word line 154 is formed on the overall surface of the resultant structure having the gate insulating layer 152, the conductive layer is patterned, thereby forming the word line 154 in the gate space 150. The conductive layer for forming the word line 154 may be formed from, for example, a doped polysilicon layer, a tungsten silicide layer, a TiN layer, and a tungsten layer, which may be sequentially stacked. The word line 154 inside the trench 110 is self-aligned with the separation layer 140 formed inside the trench 110 and the active region 120. The two word lines 154 disposed adjacent to each other inside the trench 110 are spaced apart from each other by the separation layer 140 inside the trench 140 with a predetermined distance. That is, an additional etch process to separate the two word, lines 154 inside the trench 110 is not necessary.

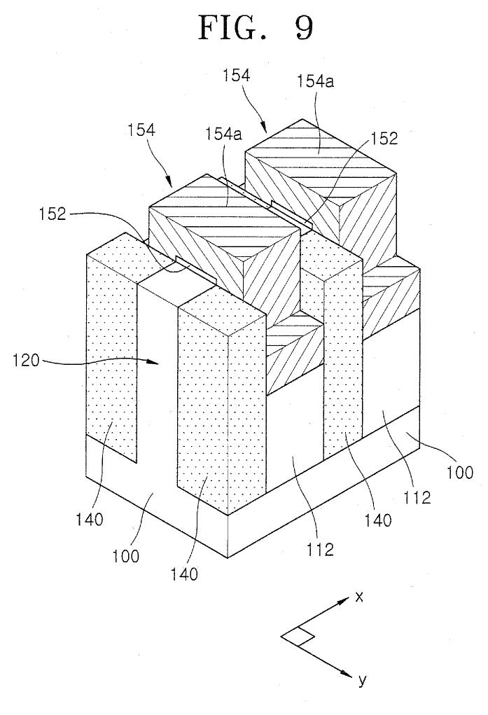

FIG. 9 is a perspective view schematically illustrating a cut-away portion indicated by “A” of FIG. 8A. In FIG. 9, the gate insulating layer 152 is not shown.

Referring to FIG. 9, a plurality of word lines 154 are formed on the fin-shaped active region 120 extending along a predetermined direction (x direction in FIG. 9) on the semiconductor substrate 100. Each word line 154 extends along a direction (y direction in FIG. 9) perpendicular to the extension direction of the active region 120.

The word line 154 inside the trench 110 is self-aligned with the separation layer 140 and the active region 120. The two neighboring word lines 154 inside the trench 110 are spaced apart from each other by the separation layer 140 inside the trench 110 with a predetermined distance. A gate 154a as a portion of the word line 154 is formed to cover an upper surface and a sidewall of the fin-shaped active region 120. In particular, the word line 154 is formed to cover a sidewall of the active region 120 inside the gate space 150 inside the trench 110. The word line 154 has a first surface facing the active region 120 inside the trench 110, and a second surface facing the separation layer 140 inside the trench 110. The gate insulating layer 152 is interposed between the first surface of the word line 154 and the active region 120, and the second surface of the word line 154 and the separation layer 140 directly contact each other. When source/drain regions (not shown) are formed inside the active region 120, a fin field effect transistor (FinFET) having a horizontal channel formed along an upper surface of the active region 120, and a vertical channel formed along a sidewall of the active region 120 can be formed on the semiconductor substrate 100.

In order to realize a FinFET using a trench by the method of fabricating a semiconductor device according to some embodiments of the present invention, a separation layer is formed inside a trench to separate two neighboring word lines formed on an isolation region and maintained with a predetermined distance. The word lines are formed to be self-aligned with the separation layer. The separation layer comprises a material having an etch selectivity with respect to an insulating layer for isolation to bury the trench.

According to some embodiments of the present invention, a separation layer is located between word lines formed adjacent to each other on an isolation region, and the separation layer comprises a material having an etch selectivity with respect to the material of an insulating layer for isolation. According to some embodiments of the present invention, it is not necessary to form a mask pattern using a photolithography process when etching an insulating layer for isolation to expose a sidewall of an active region inside a trench, and a self-aligned FinFET structure, in which word lines are formed by a self-align method between an active region and a separation layer inside a trench, is realized so that bridge generation between two word lines disposed in adjacent to each other inside the trench can be removed.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a plurality of fin-shaped active regions defined by a trench formed in a semiconductor substrate;
an isolation layer formed inside the trench, the isolation layer comprising a first insulating material;
a plurality of word lines formed on the isolation layer inside the trench, the plurality of word lines each covering a sidewall of the active region inside the trench;
a gate insulating layer formed between the active region and the word line; and
a separation layer formed between two adjacent word lines inside the trench, the separation layer comprising a second insulating material having an etch selectivity with respect to the first insulating material.

2. The semiconductor device according to claim 1, wherein the separation layer directly contacts a bottom surface of the trench.

3. The semiconductor device according to claim 1, wherein the separation layer is formed inside the trench with a shallower depth than that of the trench.

4. The semiconductor device according to claim 1, wherein the first insulating material comprises silicon oxide, and
the second insulating material comprises silicon nitride.

5. The semiconductor device according to claim 1, wherein the word line has a first surface facing the active region inside the trench, and has a second surface facing the separation layer inside the trench.

6. The semiconductor device according to claim 5, wherein the second surface of the word line directly contacts the separation layer.

7. The semiconductor device according to claim 1, wherein the active region is integrally formed with the semiconductor substrate.

8. The semiconductor device according to claim 1, wherein the active region extends along a first direction with an island shape; and
the plurality of word lines extend along a second direction perpendicular to the first direction.

9. A method of fabricating a semiconductor device comprising:
partially etching the semiconductor substrate, thereby forming a trench to define fin-shaped active regions extending along a first direction in the semiconductor substrate;
forming an isolation layer comprising a first insulating material inside the trench;
partially removing the isolation layer, thereby forming a separation space inside the trench;
filling the inside of the separation space with a separation layer comprising a second insulating material having an etch selectivity with respect to the first insulating material;
partially removing the isolation layer, thereby forming a gate space between the separation layer and the active region inside the trench while exposing respective sidewalls of the separation layer and the active region;
forming a gate insulating layer on an upper surface and a sidewall of the active region; and
forming word lines filling the gate space on the gate insulating layer.

10. The method according to claim 9, wherein forming the separation space inside the trench comprises:
forming an etch mask pattern covering a predetermined region for the word lines on the isolation layer; and
etching a portion of the isolation layer exposed through the etch mask pattern.

11. The method according to claim 10, wherein forming the separation space is performed by etching the isolation layer until a bottom surface of the trench is exposed.

12. The method according to claim 10, wherein the etching is stopped before a bottom surface of the trench is exposed.

13. The method according to claim 10, wherein the semiconductor substrate is dry-etched to form the trench, using the hard mask pattern covering the active region as an etch mask.

14. The method according to claim 13, wherein the etch mask pattern is formed both on the isolation layer and the hard mask pattern; and
the isolation layer is dry-etched to form the separation space inside the trench, using the hard mask pattern and the etch mask pattern as etch masks.

15. The method according to claim 13, wherein the isolation layer is etched back to form the gate space, using the separation layer and the hard mask pattern as etch masks.

16. The method according to claim 15, after forming the gate space, the method further comprises exposing an upper surface of the active region by removing the hard mask pattern.

17. The method according to claim 9, wherein the first insulating material comprises silicon oxide, and
the second insulating material comprises silicon nitride.

18. The method according to claim 9, wherein forming the gate insulating layer comprises thermally oxidizing an exposed surface of the active region.

19. The method according to claim 9, wherein the word lines are formed to extend in parallel with each other in a second direction that is perpendicular to the first direction.

20. The method according to claim 9, wherein each of the word lines covers an upper surface of the active region with the gate insulating layer between them, and covers a sidewall of the active region inside the gate space in the trench with the gate insulating layer between them.
